(19) United States
(12) Patent Application Publication
(10) Pub. No.: US 2021/0343753 A1
(43) Pub. Date: Nov. 4, 2021

(54) DISPLAY PANEL AND DISPLAY DEVICE

(71) Applicants: HKC Corporation Limited, Shenzhen (CN); Chongqing HKC Optoelectronics Technology Co., ltd., Chongqing (CN)

(72) Inventor: EN-Tsung CHO, Chongqing (CN)

(21) Appl. No.: 16/337,933

(22) PCT Filed: Jan. 9, 2018
(86) PCT No.: PCT/CN2018/071854

§ 371 Date: Mar. 29, 2019

(30) Foreign Application Priority Data
Jan. 5, 2018 (CN) 201810011638.3

(51) Int. Cl. H01L 27/12; H01L 27/32

(52) U.S. Cl. CPC H01L 27/1225; G02F 1/1368; H01L 27/3244

(57) ABSTRACT

The present application discloses a display panel and a display device. The display panel includes: a substrate having a plurality of pixel regions; at least one active switch formed on the substrate; a transparent conductive layer electrically connected to the active switch; an Organic Light-Emitting Diode (OLED) formed on the transparent conductive layer; and a common electrode layer covering the OLED. The active switch includes a semiconductor layer. The semiconductor layer is made of a germanium-containing semiconductor material and has an electron mobility greater than 3 cm²/vs.

### TECHNICAL FIELD

The present application relates to the technical field of display, and in particular, to a display panel, a preparation process thereof, and a display device.

### BACKGROUND

A Liquid Crystal Display (LCD) has many advantages such as thin body, power-saving, and no radiation, and thus has been widely used. Most of the LCDs on the existing market are backlight LCDs, which include an LCD panel and a backlight module. The working principle of the LCD panel is to place liquid crystal molecules in two parallel glass substrates and apply driving voltages on the two glass substrates to control the rotation direction of the liquid crystal molecules to refract the light of the backlight module to generate a picture.

Thin Film Transistor-LCD (TFT-LCD) has gradually become a leading role in the display field due to its low power consumption, excellent picture quality, and higher production yield. Similarly, the TFT-LCD includes an LCD panel and a backlight module. The LCD panel includes a Color Film Substrate (CF Substrate) (also called a color filter substrate) and a Thin Film Transistor Substrate (TFT Substrate), and transparent electrodes are disposed on opposite sides of the substrates. A Liquid Crystal (LC) molecule layer is sandwiched between two substrates. The LCD panel changes the polarization state of the light by means of the control of the LC molecule orientation by the electric field and achieves penetration and blocking of a light path by means of a polarizing plate, thereby achieving the objective of display.

Another OLED (Organic Light-Emitting Diode) display displays using self-illumination of an OLED, and has advantages such as self-illumination, wide viewing angle, almost infinite high contrast, low power consumption, and extremely high reaction speed. The OLED display also adopts a TFT to control. However, the traditional amorphous silicon structure has lower TFT mobility, and thus is not applicable to the OLED display.

### SUMMARY

One objective of the present application is to provide a display panel for improving the mobility of a semiconductor layer.

To solve the foregoing problem, the display panel provided by embodiments of the present application includes:

a display panel, which includes:

a substrate having a plurality of pixel regions;

at least one active switch formed on the substrate; and

an OLED formed on the transparent conductive layer;

the active switch includes a semiconductor layer; the semiconductor layer is made of a germanium-containing semiconductor material and is prepared by chemical vapor deposition, and the gas ratios of the preparation process thereof are: GeH₄/SiH₄=0.1-10, SiH₄/N₂O=0.1-10, and GeH₄/N₂O=0.1-10.

Optionally, the semiconductor layer includes a silicon germanium oxide. The mobility of a general amorphous silicon Thin Film Transistor (a-Si TFT) is low, and is less than 1 cm²/V-s. However, the mobility of the silicon germanium oxide can exceed 1 cm²/V-s, or even exceed 2 cm²/V-s. Germanium (Ge) is a gray-white metal that is shiny and hard and belongs to the carbon family and has chemical properties similar to those of tin and silicon in the same family. In nature, there are five isotopes of Ge, with atomic weights between 70 and 76. It can form many different organometallic compounds. The conductive ability of Ge is superior to that of general non-metals, inferior to general metals, and has a melt density of 5.32 g/cm. It has good semiconductor properties such as electron mobility and hole mobility. Doping Ge into the semiconductor layer 40 of the active switch can effectively improve the mobility and meet the requirements of OLED display.

Optionally, the semiconductor layer includes a first doping layer, an active layer, and a second doping layer; the active layer is provided between the first doping layer and the second doping layer, and the active layer includes the silicon germanium oxide.

Optionally, the first doping layer, the active layer, and the second doping layer are located in the same layer; the active switch further includes:

a gate insulating layer formed on the semiconductor layer;

a gate metal layer formed on the gate insulating layer;

a dielectric layer formed on the gate metal layer; and

a source metal layer and a drain metal layer formed on the dielectric layer;

the source metal layer penetrates through the dielectric layer and the gate insulating layer and is electrically connected to the first doping layer, and the drain metal layer penetrates through the dielectric layer and the gate insulating layer and is electrically connected to the second doping layer.

This is at least one active switch structure with the gate metal layer located above the semiconductor layer and is beneficial to improve the response speed of the active switch.

Optionally, the first doping layer, the active layer, and the second doping layer are located in the same layer; the active switch further includes:

a gate insulating layer formed on the semiconductor layer;

a gate metal layer formed on the gate insulating layer;

a dielectric layer formed on the gate metal layer; and

a source metal layer and a drain metal layer formed on the dielectric layer;

the gate insulating layer and the gate metal layer are equal in width, the gate metal layer is located between the source metal layer and the drain metal layer, the source metal layer penetrates through the dielectric layer and is electrically connected to the first doping layer, and the drain metal layer penetrates through the dielectric layer and is electrically connected to the second doping layer.

This is at least one active switch structure with the gate metal layer located above the semiconductor layer and is beneficial to improve the response speed of the active switch. In addition, the gate insulating layer is only limited below the gate metal layer, and does not exist in other part, and thus the total stacked thickness of the layers is reduced correspondingly, which is beneficial to reduce the thickness of the panel.

Optionally, a first insulating layer formed on the source metal layer, the drain metal layer and the dielectric layer;

a second insulating layer formed on the first insulating layer;

the transparent conductive layer is formed on the first insulating layer, is embedded between the first insulating layer and the second insulating layer, and is electrically connected to the drain metal layer; and

a third insulating layer formed on the second insulating layer;

the common electrode layer is formed on the third insulating layer:

the OLED and the third insulating layer are located on the same layer, and are electrically connected to the transparent conductive layer and the common electrode layer, respectively.

The transparent electrode layer and the common electrode layer covering the drain metal layer are used as two electrodes of the OLED, to drive the OLEDs in the middle part to emit light. Compared to the structure connected by a via hole, the drain metal layer, the transparent electrode layer, the OLED, and the common electrode layer are a tightly stacked structure, and thus good electrical contact performance and compact structure are obtained, and it is beneficial to reduce the thickness of the display panel.

Optionally, the common electrode layer entirely covers the third insulating layer. An etching process is not additionally required for preparing the common electrode layer, simplifying the technological process and reducing the production cost.

Optionally, the active layer is provided under the gate metal layer, and the width of the active layer is less than or equal to that of the gate metal layer.

Optionally, the active switch is a low-temperature poly-silicon TFT The silicon TFT can be divided into a Poly-silicon (Poly-Si) TFT and an Amorphous Silicon (a-Si) TFT, and the difference thereof is that the transistor characteristic is different. The molecular structures of poly-silicon are arranged neatly and directionally in a grain, and thus, the electron mobility is 200-300 times faster than the disordered amorphous silicon. Moreover, the poly-silicon products mainly include two products. i.e., High-Temperature Poly-silicon (HTPS) and Low-Temperature Poly-silicon (LTPS). The LTPS TFT display panel uses excimer laser as a heat source in the packaging process. After the laser light passes through a projection system, a laser beam with uniform energy distribution is generated and projected onto a glass substrate of an amorphous silicon structure. After the glass substrate of the amorphous silicon structure absorbs the energy of the excimer laser, it is converted into a poly-silicon structure. Since the entire process is completed below 600° C., it is applicable to general glass substrates, and the universality is good.

Another objective of the present application is to provide a display device, which improves the mobility of a semiconductor layer.

A display device includes a control member, and the display panel according to the present application.

Germanium (Ge) is a gray-white metal that is shiny and hard, and belongs to the carbon family and has chemical properties similar to those of tin and silicon in the same family. In nature, there are five isotopes of Ge, with atomic weights between 70 and 76. It can form many different organometallic compounds. The conductive ability of Ge is superior to that of general non-metals, inferior to general metals, and has a melt density of 5.32 g/cm. It has good semiconductor properties such as electron mobility and hole mobility. Doping Ge into the semiconductor layer of the TFT can effectively improve the mobility and meet the requirements of OLED display.

### BRIEF DESCRIPTION OF DRAWINGS

The drawings are included to provide further understanding of embodiments of the present application, which constitute a part of the specification and illustrate the embodiments of the present application, and describe the principles of the present application together with the text description. Apparently, the accompanying drawings in the following description show merely some embodiments of the present application, and a person of ordinary skill in the art may still derive other accompanying drawings from these accompanying drawings without creative efforts.

In the accompanying drawings:

FIG. 1 is a structural schematic diagram of a display panel according to an embodiment of the present application;

FIG. 2 is a structural schematic diagram of a display panel according to another embodiment of the present application;

FIG. 3 is a structural schematic diagram of a display panel according to another embodiment of the present application;

FIG. 4 is a structural schematic diagram of a display panel according to another embodiment of the present application; and

FIG. 5 is a schematic diagram of a display device according to an embodiment of the present application.

### DETAILED DESCRIPTION

The specific structure and function details of the present application are merely representative, and are intended to describe exemplary embodiments of the present application. However, the present application can be specifically embodied in many alternative forms, and should not be interpreted to be limited to the embodiments described herein.

In the description of the present application, it should be understood that, orientation or position relationships indicated by the terms “center”, “tansversal”, “upper”, “lower”, “left”, “right”, “vertical”, “horizontal”, “top”, “bottom”, “inner”, “outer”, etc. are based on the orientation or position relationships as shown in the drawings, for ease of the description of the present application and simplifying the description only, rather than indicating or implying that the indicated device or element must have a particular orientation or be constructed and operated in a particular orientation. Therefore, these terms should not be understood as a limitation to the present application. In addition, the terms “first”, “second” are merely for a descriptive purpose, and cannot to be understood to indicate or imply a relative importance, or implicitly indicate the number of the indicated technical features.

Hence, the features defined by “first”, “second” can explicitly or implicitly include one or more of the features. In the description of the present application, “a plurality of” means two or more, unless otherwise stated. In addition, the term “include”, and any variations thereof are intended to cover a non-exclusive inclusion.

In the description of the present application, it should be understood that, unless otherwise specified and defined, the terms “install”, “connected with”, “connected to” should be comprehended in a broad sense. For example, these terms may be comprehended as being fixedly connected, detachably connected or integrally connected; mechanically connected or electrically connected; or directly connected or indirectly connected through an intermediate medium, or in an internal communication between two elements. The specific meanings about the foregoing terms in the present application may be understood for those skilled in the art according to specific circumstances.

The terms used herein are merely for the purpose of describing the specific embodiments, and are not intended to limit the exemplary embodiments. As used herein, the singular forms “a”, “an” are intended to include the plural forms as well, unless otherwise indicated in the context clearly. It will be further understood that the terms “comprise” and/or “include” used herein specify the presence of the stated features, integers, steps, operations, elements and/or components, but do not preclude the presence or addition of one or more other features, integers, steps, operations, elements, components and/or combinations thereof.

In the drawings, units of similar structures are represented by the same reference numeral.

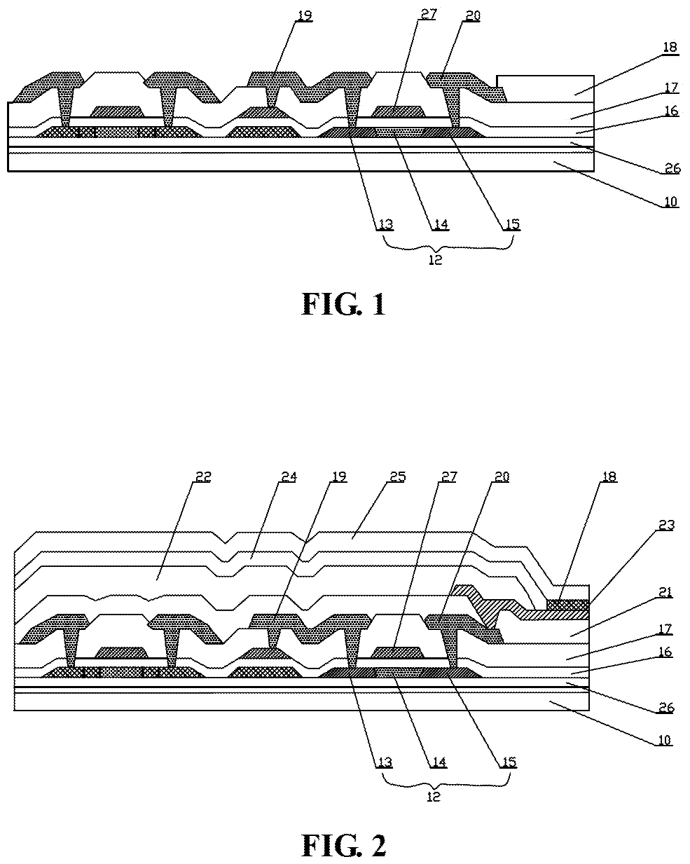

The display panel and the display device of the present application are further described in details below with reference to embodiments of FIGS. 1-5.

The display panel of this embodiment includes:

a substrate 10 having a plurality of pixel regions;

at least one active switch 11 formed on the substrate 10;

a transparent conductive layer 23 electrically connected to the active switch 11;

an OLED 18 formed on the transparent conductive layer 23; and

a common electrode layer 25 covering the OLED 18;

the active switch includes a semiconductor layer 12; the semiconductor layer is made of a germanium-containing semiconductor material and is prepared by chemical vapor deposition, and the gas ratios of the preparation process thereof are: GeH₄/SiH₄=0.1-10, SiH₄/N₂O=0.1-10, and GeH₄/N₂O=0.1-10.

Germanium (Ge) is a gray-white metal that is shiny and hard, and belongs to the carbon family and has chemical properties similar to those of tin and silicon in the same family. In nature, there are five isotopes of Ge, with atomic weights between 70 and 76. It can form many different organometallic compounds. The conductive ability of Ge is superior to that of general non-metals, inferior to general metals, and has a melt density of 5.32 g/cm. It has good semiconductor properties such as electron mobility and hole mobility. Doping Ge into the semiconductor layer of the TFT can effectively improve the mobility and meet the requirements of OLED display.

Mobility refers to the average drift velocity of carriers generated at a unit electric field intensity, and the unit thereof is cm/(V·s). Mobility represents the electric conductivity of the carriers, and the mobility and the carrier (electron or hole) concentration decide the electric conductivity of the semiconductor. The mobility is inversely proportional to the effective mass and the scattering probability of the carriers. Mobility is an important parameter for characterizing semiconductors. The higher the mobility is, the faster the device runs, and the higher the cut-off frequency is. Therefore, the present application can effectively improve the response speed of the display panel.

Specifically speaking, the germanium-containing semiconductor material is a silicon germanium oxide (SixGeyOz) compound or an oxygen-enriched germanium compound, and the annealing temperature (Depo. Temp) of these compounds is generally between 170° C. and 370° C. The oxygen-enriched germanium compound includes, but is not limited to, germanium oxide (GeOx), germanium nitride (GeNx), germanium oxynitride (GeOxNy), etc.; and the silicon germanium oxide (SixGeyOz) compound or the oxygen-enriched germanium compound are nano materials.

Taking the silicon germanium oxide (SixGeyOz) compound for example, the atomic numbers x and y of Silicon (Si) and Germanium (Ge) are respectively:

Si:x=0.1-1

Ge:y=0.1-1

Z=1−x−y

The mobility of a general amorphous silicon Thin Film Transistor (a-Si TFT) is low, and is less than 1 cm²/V-s. However, the mobility of the silicon germanium oxide can exceed 1 cm²/V-s, or even exceed 2 cm²/V-s. Germanium (Ge) is a gray-white metal that is shiny and hard, and belongs to the carbon family and has chemical properties similar to those of tin and silicon in the same family. In nature, there are five isotopes of Ge, with atomic weights between 70 and 76. It can form many different organometallic compounds. The conductive ability of Ge is superior to that of general non-metals, inferior to general metals, and has a melt density of 5.32 g/cm. It has good semiconductor properties such as electron mobility and hole mobility. Doping Ge into the semiconductor layer 40 of the active switch can effectively improve the mobility and meet the requirements of OLED display.

Optionally, the electron mobility of the semiconductor layer is greater than 3 cm²/V-s.

Optionally, the active switch is an LTPS TFT.

The active switch includes a semiconductor layer 12; the semiconductor layer 12 includes a first doping layer 13, an active layer 15, and a second doping layer 14; the active layer 15 is provided between the first doping layer 13 and the second doping layer 14, and the active layer 15 includes the silicon germanium oxide; the first doping layer 13, the active layer 15, and the second doping layer 14 are located in the same layer.

The active switch further includes:

a gate insulating layer 16 formed on the semiconductor layer 12;

a gate metal layer 27 formed on the gate insulating layer 16;

a dielectric layer 17 formed on the gate metal layer 27; and

a source metal layer 19 and a drain metal layer 20 formed on the dielectric layer 17;

the source metal layer 19 penetrates through the dielectric layer 17 and the gate insulating layer 16 and is electrically connected to the first doping layer 13, and the drain metal layer 20 penetrates through the dielectric layer 17 and the gate insulating layer 16 and is electrically connected to the second doping layer 14.

Optionally, the active layer 15 is provided under the gate metal layer 27, and the width of the active layer 15 is less than or equal to that of the gate metal layer 27.

Optionally, the substrate 10 is a glass substrate 10. The glass substrate 10 may be added with a buffer layer 26. The semiconductor layer 12 is attached to the buffer layer 26, and the adhesive force is strong.

Optionally, the active switch is an LTPS TFT. The first doping layer 13 and the second doping layer 14 may adopt an oxygen-enriched germanium compound to further improve the mobility.

This embodiment provides at least one active switch structure with the gate metal layer 27 located above the semiconductor layer 12, which is beneficial to improve the response speed of the active switch. The silicon TFT can be divided into a Poly-Si TFT and an a-Si TFT, and the difference thereof is that the transistor characteristic is different. The molecular structures of poly-silicon are arranged neatly and directionally in a grain, and thus, the electron mobility is 200-300 times faster than the disordered amorphous silicon. Moreover, the poly-silicon products mainly include two products, i.e., HTPS and LTPS. The LTPS TFT display panel uses excimer laser as a heat source in the packaging process. After the laser light passes through a projection system, a laser beam with uniform energy distribution is generated and projected onto a glass substrate 10 of an amorphous silicon structure.

After the glass substrate 10 of the amorphous silicon structure absorbs the energy of the excimer laser, it is converted into a poly-silicon structure. Since the entire process is completed below 600° C., it is applicable to general glass substrates 10, and the universality is good.

With reference to FIG. 2, the display panel provided in this embodiment includes:

a substrate 10 having a plurality of pixel regions;

at least one active switch formed on the substrate 10; and

an OLED 18 formed on the transparent conductive layer;

the active switch includes a semiconductor layer 12; the semiconductor layer 12 includes a first doping layer 13, an active layer 15, and a second doping layer 14; the active layer 15 is provided between the first doping layer 13 and the second doping layer 14, and the active layer 15 includes the silicon germanium oxide; the first doping layer 13, the active layer 15, and the second doping layer 14 are located in the same layer.

The active switch further includes:

a gate insulating layer 16 formed on the semiconductor layer 12;

a gate metal layer 27 formed on the gate insulating layer 16;

a dielectric layer 17 formed on the gate metal layer 27: and

a source metal layer 19 and a drain metal layer 20 formed on the dielectric layer 17;

the source metal layer 19 penetrates through the dielectric layer 17 and the gate insulating layer 16 and is electrically connected to the first doping layer 13, and the drain metal layer 20 penetrates through the dielectric layer 17 and the gate insulating layer 16 and is electrically connected to the second doping layer 14.

The display panel further includes:

a first insulating layer 21 formed on the source metal layer 19, the drain metal layer 20 and the dielectric layer 17;

a second insulating layer 22 formed on the first insulating layer 21;

the transparent conductive layer 23 is formed on the first insulating layer 21, is embedded between the first insulating layer 21 and the second insulating layer 22, and is electrically connected to the drain metal layer 20; and

a third insulating layer 24 formed on the second insulating layer 22;

the common electrode layer 25 is formed on the third insulating layer 24;

the OLED 18 and the third insulating layer 24 are located on the same layer, and are electrically connected to the transparent conductive layer 23 and the common electrode layer 25, respectively.

Optionally, the common electrode 25 entirely covers the third insulating layer 24. The active layer 15 is provided under the gate metal layer 27, and the width of the active layer 15 is less than or equal to that of the gate metal layer 27.

Optionally, the substrate 10 is a glass substrate 10. The glass substrate 10 may be added with a buffer layer 26. The semiconductor layer 12 is attached to the buffer layer 26, and the adhesive force is strong.

The transparent electrode layer and the common electrode layer 25 covering the drain metal layer 20 are used as two electrodes of the OLED 18, to drive the OLEDs 18 in the middle part to emit light. Compared to the structure connected by a via hole, the drain metal layer 20, the transparent electrode layer, the OLED 18, and the common electrode layer 25 are a tightly stacked structure, and thus good electrical contact performance and compact structure are obtained, and it is beneficial to reduce the thickness of the display panel.

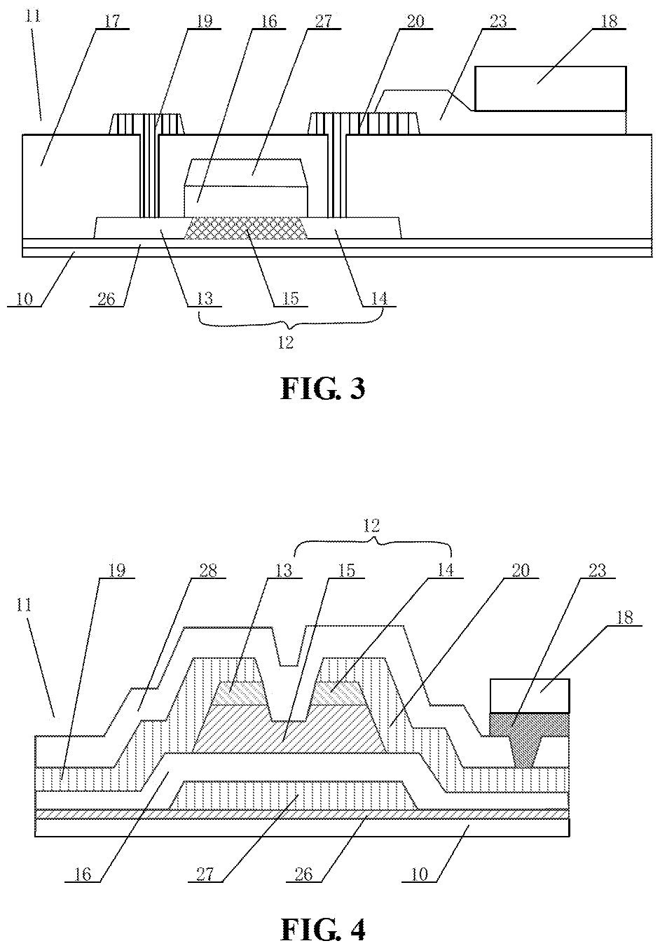

With reference to FIG. 3, the display panel provided in this embodiment includes:

a substrate 10 having a plurality of pixel regions;

at least one active switch formed on the substrate 10; and

an OLED 18 formed on the transparent conductive layer:

the active switch includes a semiconductor layer 12; the semiconductor layer 12 includes a first doping layer 13, an active layer 15, and a second doping layer 14; the active layer 15 is provided between the first doping layer 13 and the second doping layer 14, and the active layer 15 includes the silicon germanium oxide; the first doping layer 13, the active layer 15, and the second doping layer 14 are located in the same layer.

The active switch further includes:

a gate insulating layer 16 formed on the semiconductor layer 12;

a gate metal layer 27 formed on the gate insulating layer 16;

a dielectric layer 17 formed on the gate metal layer 27;

a source metal layer 19 and a drain metal layer 20 formed on the dielectric layer 17; and

a transparent conductive layer 23 formed on the drain metal layer 20 and electrically connected to the drain metal layer 20;

the OLED 18 is electrically connected to the transparent conductive layer 23.

The gate insulating layer 16 and the gate metal layer 27 are equal in width, the gate metal layer 27 is located between the source metal layer 19 and the drain metal layer 20, the source metal layer 19 penetrates through the dielectric layer 17 and is electrically connected to the first doping layer 13, and the drain metal layer 20 penetrates through the dielectric layer 17 and is electrically connected to the second doping layer 14.

Optionally, the active layer 15 is provided under the gate metal layer 27, and the width of the active layer 15 is less than or equal to that of the gate metal layer 27.

Optionally, the substrate 10 is a glass substrate 10. The glass substrate 10 may be added with a buffer layer 26. The semiconductor layer 12 is attached to the buffer layer 26, and the adhesive force is strong.

This embodiment provides another active switch structure with the gate metal layer 27 located above the semiconductor layer 12, which is beneficial to improve the response speed of the active switch. In addition, the gate insulating layer 16 is only limited below the gate metal layer 27, and does not exist in other part, and thus the total stacked thickness of the layers is reduced correspondingly, which is beneficial to reduce the thickness of the panel.

With reference to FIG. 4, the display panel provided in this embodiment includes:

a substrate 10 having a plurality of pixel regions;

at least one active switch formed on the substrate 10; and

an OLED 18 formed on the transparent conductive layer;

The active switch sequentially includes: a gate metal layer 27, a gate insulating layer 16, a semiconductor layer 12, a source metal layer 19, a drain metal layer 20, a passivation layer 28, and a transparent conductive layer 23: the semiconductor 12 includes an active layer 15 formed on the gate metal layer 27, and a first doping layer 13 and a second doping layer 14 formed above the active layer 15; the source metal layer 19 is formed on the first doping layer 13; the drain metal layer 20 is formed on the second doping layer 14; and the transparent conductive layer 23 penetrates through the passivation layer 28 and is electrically connected to the drain metal layer 20. The active layer 15 includes a silicon germanium oxide.

Optionally, the active switch is an LTPS TFT. The first doping layer 13 and the second doping layer 14 may adopt an oxygen-enriched germanium compound to further improve the mobility.

Optionally, the substrate 10 is a glass substrate 10. A buffer layer 26 may be added between the active switch and the glass substrate 10 to improve the adhesive force of the active switch.

The display panel according to the foregoing embodiments may be any one of the following: a Twisted Nematic (TN) display panel, a Super Twisted Nematic (STN) display panel, an In-Plane Switching (IPS) display panel, a Vertical Alignment (VA) display panel, and a curved-surface display panel, and may be an LCD panel, a plasma panel, an OLED panel, a QLED panel, etc.

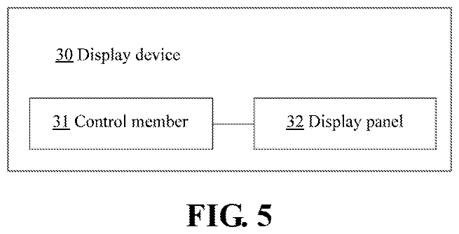

With reference to FIG. 5, this embodiment provides a display device 30. The display device 30 includes a control member 31, and the foregoing display panel 32. The above describes in detail by taking the display panel for example. It should be noted that the description on the display panel structure above is also applicable to the display device according to the embodiment of the present application. When the display device according to the embodiment of the present application is an LCD, the LCD includes a backlight module, which may be used as a light source for supplying sufficient brightness and uniformly distributed light. The backlight module of this embodiment may be front-light or backlight. It should be noted that the backlight module of this embodiment is not limited thereto.

The contents above are further detailed descriptions of the present application in conjunction with optional embodiments, and the specific implementation of the present application is not limited to these descriptions. It will be apparent to those skilled in the art that various simple deductions or substitutions may be made without departing from the spirit of the present application, and should be considered to be within the scope of protection of the present application.

What is claimed is:

1. A display panel, comprising:
a substrate having a plurality of pixel regions;
at least one active switch formed on the substrate;
a transparent conductive layer electrically connected to the active switch;
an Organic Light-Emitting Diode (OLED) formed on the transparent conductive layer; and
a common electrode layer covering the OLED;
the active switch comprises a semiconductor layer; the semiconductor layer is made of a germanium-containing semiconductor material and is prepared by chemical vapor deposition, and the gas ratios of the preparation process thereof are: GeH₄/SiH₄=0.1-10, SiH₄/N₂O=0.1-10, and GeH₄/N₂O=0.1-10;
the semiconductor layer comprises a silicon germanium oxide; the semiconductor layer comprises a first doping layer, an active layer, and a second doping layer; the active layer is provided between the first doping layer and the second doping layer, and the active layer comprises the silicon germanium oxide;
the first doping layer, the active layer, and the second doping layer are located in the same layer; the active switch further comprises:
a gate insulating layer formed on the semiconductor layer;
a gate metal layer formed on the gate insulating layer:
a dielectric layer formed on the gate metal layer;
a source metal layer and a drain metal layer formed on the dielectric layer;
the gate insulating layer and the gate metal layer are equal in width, the gate metal layer is located between the gate metal layer and the drain metal layer, the source metal layer penetrates through the dielectric layer and is electrically connected to the first doping layer, and the drain metal layer penetrates through the dielectric layer and is electrically connected to the second doping layer;
a first insulating layer formed on the source metal layer, the drain metal layer and the dielectric layer;
a second insulating layer formed on the first insulating layer;
the transparent conductive layer is formed on the first insulating layer, is embedded between the first insulating layer and the second insulating layer, and is electrically connected to the drain metal layer; and
a third insulating layer formed on the second insulating layer;
the common electrode layer is formed on the third insulating layer;
the OLED and the third insulating layer are located on the same layer, and are electrically connected to the transparent conductive layer and the common electrode layer, respectively;
the common electrode layer entirely covering the third insulating layer;
the active switch is a low-temperature poly-silicon thin film transistor.

2. A display panel, comprising:
a substrate having a plurality of pixel regions;
at least one active switch formed on the substrate;
a transparent conductive layer electrically connected to the active switch;
an OLED formed on the transparent conductive layer; and
a common electrode layer covering the OLED;
the active switch comprises a semiconductor layer; the semiconductor layer is made of a germanium-containing semiconductor material and is prepared by chemical vapor deposition, and the gas ratios of the preparation process thereof are: GeH₄/SiH₄=0.1-10, SiH₄/N₂O=0.1-10, and GeH₄/N₂O=0.1-10.

3. The display panel according to claim 2, wherein the semiconductor layer comprises a silicon germanium oxide.

4. The display panel according to claim 3, wherein the semiconductor layer comprises a first doping layer, an active layer, and a second doping layer; the active layer is provided between the first doping layer and the second doping layer; and the active layer comprises the silicon germanium oxide.

5. The display panel according to claim 4, wherein the first doping layer, the active layer, and the second doping layer are located on the same layer; the active switch further comprises:
a gate insulating layer formed on the semiconductor layer;
a gate metal layer formed on the gate insulating layer;
a dielectric layer formed on the gate metal layer; and
a source metal layer and a drain metal layer formed on the dielectric layer;
the source metal layer penetrates through the dielectric layer and the gate insulating layer and is electrically connected to the first doping layer, and the drain metal layer penetrates through the dielectric layer and the gate insulating layer and is electrically connected to the second doping layer.

6. The display panel according to claim 5, further comprising:
a first insulating layer formed on the source metal layer, the drain metal layer and the dielectric layer;
a second insulating layer formed on the first insulating layer;
the transparent conductive layer is formed on the first insulating layer, is embedded between the first insulating layer and the second insulating layer, and is electrically connected to the drain metal layer; and
a third insulating layer formed on the second insulating layer;
the common electrode layer is formed on the third insulating layer;
the OLED and the third insulating layer are located on the same layer, and are electrically connected to the transparent conductive layer and the common electrode layer, respectively.

7. The display panel according to claim 6, wherein the common electrode layer entirely covers the third insulating layer.

8. The display panel according to claim 5, wherein the active layer is provided under the gate metal layer, and the width of the active layer is less than or equal to that of the gate metal layer.

9. The display panel according to claim 4, wherein the first doping layer, the active layer, and the second doping layer are located on the same layer; the active switch further comprises:
a gate insulating layer formed on the semiconductor layer:
a gate metal layer formed on the gate insulating layer:
a dielectric layer formed on the gate metal layer; and
a source metal layer and a drain metal layer formed on the dielectric layer;
the gate insulating layer and the gate metal layer are equal in width, the gate metal layer is located between the source metal layer and the drain metal layer, the source metal layer penetrates through the dielectric layer and is electrically connected to the first doping layer, and the drain metal layer penetrates through the dielectric layer and is electrically connected to the second doping layer.

10. The display panel according to claim 9, further comprising:
a first insulating layer formed on the source metal layer, the drain metal layer and the dielectric layer;
a second insulating layer formed on the first insulating layer;
the transparent conductive layer is formed on the first insulating layer, is embedded between the first insulating layer and the second insulating layer, and is electrically connected to the drain metal layer; and
a third insulating layer formed on the second insulating layer;
the common electrode layer is formed on the third insulating layer;
the OLED and the third insulating layer are located on the same layer, and are electrically connected to the transparent conductive layer and the common electrode layer, respectively.

11. The display panel according to claim 10, wherein the common electrode layer entirely covers the third insulating layer.

12. The display panel according to claim 9, wherein the active layer is provided under the gate metal layer, and the width of the active layer is less than or equal to that of the gate metal layer.

13. A display device, comprising:
a control member, and a display panel;
the display panel comprises:
a substrate having a plurality of pixel regions;
at least one active switch formed on the substrate;
a transparent conductive layer electrically connected to the active switch;
an OLED formed on the transparent conductive layer; and
a common electrode layer covering the OLED;
the active switch comprises a semiconductor layer; the semiconductor layer is made of a germanium-containing semiconductor material and is prepared by chemical vapor deposition, and the gas ratios of the preparation process thereof are: GeH₄/SiH₄=0.1-10, SiH₄/N₂O=0.1-10, and GeH₄/N₂O=0.1-10.

14. The display device according to claim 13, wherein the semiconductor layer comprises a silicon germanium oxide.

15. The display device according to claim 14, wherein the semiconductor layer comprises a first doping layer, an active layer, and a second doping layer; the active layer is provided between the first doping layer and the second doping layer; and the active layer comprises the silicon germanium oxide.

16. The display device according to claim 15, wherein the first doping layer, the active layer, and the second doping layer are located on the same layer; the active switch further comprises:
a gate insulating layer formed on the semiconductor layer;
a gate metal layer formed on the gate insulating layer;
a dielectric layer formed on the gate metal layer; and
a source metal layer and a drain metal layer formed on the dielectric layer;
the source metal layer penetrates through the dielectric layer and the gate insulating layer and is electrically connected to the first doping layer, and the drain metal layer penetrates through the dielectric layer and the gate insulating layer and is electrically connected to the second doping layer.

17. The display device according to claim 15, wherein the first doping layer, the active layer, and the second doping layer are located on the same layer; the active switch further comprises:
a gate insulating layer formed on the semiconductor layer;
a gate metal layer formed on the gate insulating layer:
a dielectric layer formed on the gate metal layer; and
a source metal layer and a drain metal layer formed on the dielectric layer;
the gate insulating layer and the gate metal layer are equal in width, the gate metal layer is located between the source metal layer and the drain metal layer, the source metal layer penetrates through the dielectric layer and is electrically connected to the first doping layer, and the drain metal layer penetrates through the dielectric layer and is electrically connected to the second doping layer.

18. The display device according to claim 17, wherein the display panel further comprises:
a first insulating layer formed on the source metal layer, the drain metal layer and the dielectric layer;
a second insulating layer formed on the first insulating layer;
the transparent conductive layer is formed on the first insulating layer, is embedded between the first insulating layer and the second insulating layer, and is electrically connected to the drain metal layer; and
a third insulating layer formed on the second insulating layer;
the common electrode layer is formed on the third insulating layer;
the OLED and the third insulating layer are located on the same layer and are electrically connected to the transparent conductive layer and the common electrode layer, respectively.

19. The display device according to claim 18, wherein the common electrode layer entirely covers the third insulating layer.

20. The display device according to claim 17, wherein the active layer is provided under the gate metal layer, and the width of the active layer is less than or equal to that of the gate metal layer.
